(19) United States
(12) Patent Application Publication
(10) Pub. No.: US 2019/0120471 A1
(43) Pub. Date: Apr. 25, 2019

(54) MULTI-FUNCTION WALL SWITCH

(71) Applicant: Essential Products, Inc., Palo Alto, CA (US)

(72) Inventors: Evan Abraham Witty, San Francisco, CA (US); John Michael Stefanski, San Francisco, CA (US); Raemond Isamu Bergstrom-Wood, San Francisco, CA (US)

(21) Appl. No.: 16/164,519

(22) Filed: Oct. 18, 2018

Related U.S. Application Data
(60) Provisional application No. 62/574,930, filed on Oct. 20, 2017.

(51) Int. Cl. F21V 23/04; H05B 37/02; F21S 8/00; H03K 17/945; H03K 17/96

(52) U.S. Cl. CPC F21V 23/0442; H05B 37/0227; H03K 17/962; H03K 17/945; F21S 8/035

(57) ABSTRACT

Multi-function wall switches are described. A wall switch can include a master assembly and daisy-chained slave assemblies. The master assembly can include more components than the slave assemblies to implement more functionality in a single assembly.

### PRIORITY

This application claims priority to U.S. Provisional Patent Application No. 62/574,930, entitled “Multi-Function Light Switch Device,” by Witty et al., and filed on Oct. 20, 2017. The content of the above-identified application is incorporated herein by reference in its entirety.

### TECHNICAL FIELD

This disclosure relates to a wall switch, and in particular a master-slave configuration of light switch assemblies to provide multiple functions.

### BACKGROUND

Wall-mounted light switches are installed throughout a home to turn on or off lights, for example, via electrical outlets coupled with lamps having light bulbs. Often, the light switches are installed in high-traffic areas of the home to control a lamp in the same room.

### BRIEF DESCRIPTION OF THE DRAWINGS

FIG. 1 illustrates an example of a master switch.

FIG. 2 illustrates examples of a master switch and a slave switch.

FIG. 3 illustrates an example of trim panels.

FIG. 4 illustrates another example of trim panels.

FIG. 5 illustrates an example of master and slave configurations.

FIG. 6 illustrates an example of coupling a trim with a switch assembly.

FIG. 7 illustrates another example of coupling trim with a switch assembly.

FIG. 8 illustrates an example of coupling a slave switch with a master switch.

FIG. 9 illustrates another example of coupling a slave switch with a master switch.

FIG. 10 illustrates an example of a trim panel for a master-slave configuration.

FIG. 11 illustrates an example of a master with two slave configuration.

FIG. 12 illustrates another example of a master-slave configuration.

FIG. 13 illustrates a master assembly including more functionality than a slave assembly.

FIG. 14 illustrates an example of a motion detector implemented within a master assembly.

FIG. 15 illustrates another example of a motion detector implemented within a master assembly.

FIG. 16 illustrates an example of a home lighting control.

FIG. 17 illustrates another example of a home lighting control.

FIG. 18 illustrates an example of a block diagram for a master and slave assembly operation.

FIG. 19 illustrates an example of a device for a master assembly or a slave assembly.

FIGS. 20 and 21 illustrate examples of using an ambient light sensor.

### DETAILED DESCRIPTION

This disclosure describes devices and techniques for a multi-function wall switch. In one example, a modular wall switch can include a master assembly having components (e.g., circuitry, sensors, etc.) to implement a variety of functionalities including touch sensitivity used to indicate whether to turn on or off a light, light emitting diodes (LEDs) as visual indicators regarding the state of the light and other information, and light dimming, as well as more complex functionalities such as motion detection, wireless networking, alternating current (AC)/direct current (DC) power conversion, backup battery, etc. Slave assemblies can be coupled with the master assembly to provide the capability to turn on or off other lights but lack the more complex functionalities. Many slave assemblies can be “daisy-chained” to a single master assembly. A single trim piece can also be attached to the front of the master-slave configuration of the multi-function wall switch to provide a single aesthetic look for a user. This combination of master and slave assemblies can result in reduced costs because the more complex functionalities only need to be implemented within the master assembly to implement a wall switch.

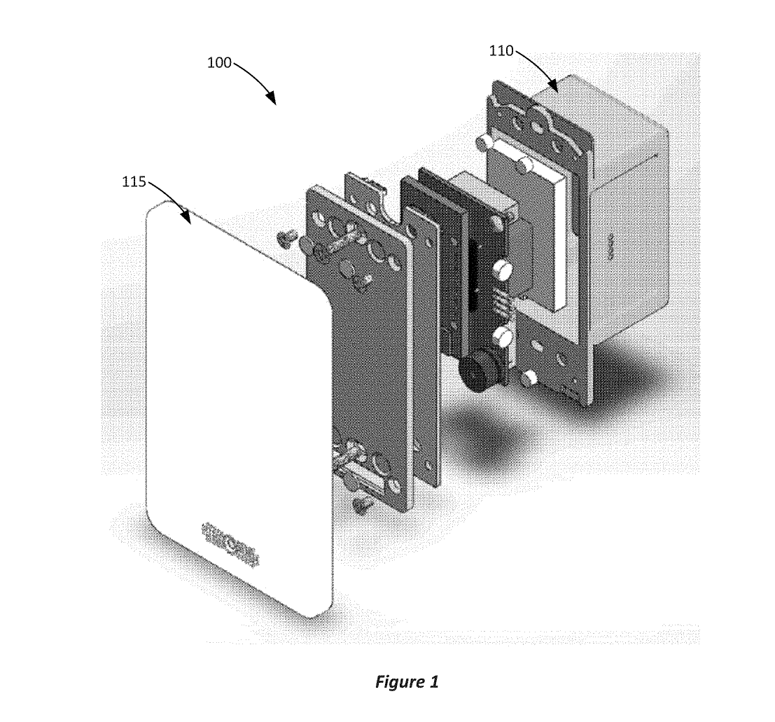

In more detail, FIG. 1 illustrates an example of a master switch. In FIG. 1, master switch 100 includes master assembly 110 with trim panel 115. Master assembly 110 can include a variety of mechanical, electromechanical, and electrical components to implement a multi-function wall switch, for example, turn on or off lights in an environment. Master assembly 110 can also include circuitry and other hardware and/or software components to enable motion detection, processor or controller circuitry, wireless networking (e.g., transceivers), and alternating current (AC)/direct current (DC) power conversion. Additionally, master assembly 110 can include a battery to provide a source of backup power if the electrical system of the home is not operational.

A user can interact with trim panel 115, for example, touch trim panel 115 to turn on or off lights (e.g., light bulbs of lamps plugged into electrical sockets), ceiling fans, or other electronics within the environment. No toggle switch is present on trim panel 115 because master assembly 110 can include touch sensitive circuitry to determine whether a finger (or multiple fingers) has contacted trim panel 115. In some implementations, the touch sensitive circuitry can implement a capacitive touch determination and trim panel 115 can provide the touch area that the touch sensitive circuitry determines whether a finger has been placed upon the touch area.

In some implementations, the trim panel can be somewhat transparent (e.g., not opaque) such that lights (e.g., light emitting diodes (LEDs)) mounted upon master assembly 110 can be turned on and the lights can be visible through the trim panel. For example, in FIG. 1, lights can be behind trim panel 115 when it is coupled with master assembly 110. The lights can provide a visual indicator as to the state of the switch, for example, indicating that the light or other electronic device that it is controlling is on. In another example, if master assembly 110 implements a dimmer, then the user can increase or decrease the dimming of the light by moving a finger along trim panel 115. Based on the intensity of the light, the LEDs can be illuminating at different intensities, a different number of LEDs can be turned on to indicate the amount of dimming, etc.

In some implementations, master assembly 110 can also include a speaker or a microphone. For example, as the user interacts with trim panel 110, sounds can be generated and played back via the speaker.

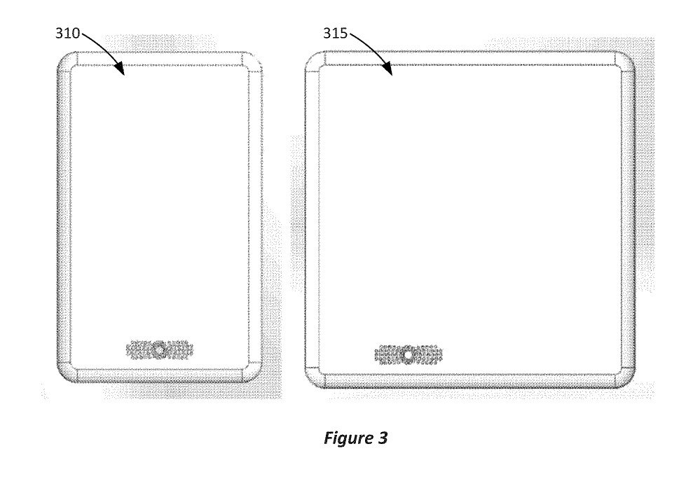

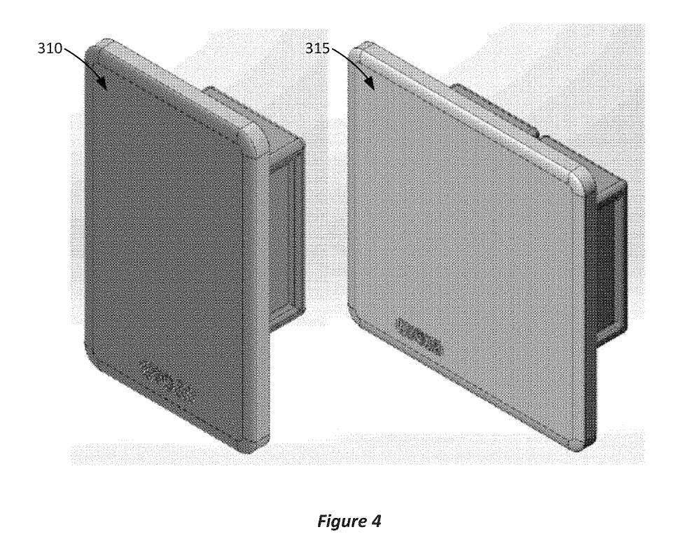

Trim panel 115 can be an aesthetically pleasing plate or surface for the user to interact with to activate some of the functionalities of master assembly 110, for example, turning on or off a light. FIG. 3 illustrates an example of trim panels. In FIG. 3, trim panel 310 can be used if a single master assembly 110 is used for a wall switch. By contrast, if master assembly 110 is daisy chained with a slave assembly (as discussed later), then a larger trim piece 315 can be provided. Thus, with trim piece 315, multiple assemblies can be covered by a single trim piece to provide a more aesthetically pleasing plate that is larger for a user to interact with. FIG. 4 illustrates another example of trim panels. For example, FIG. 4 illustrates different perspective views of trim panels 310 and 315.

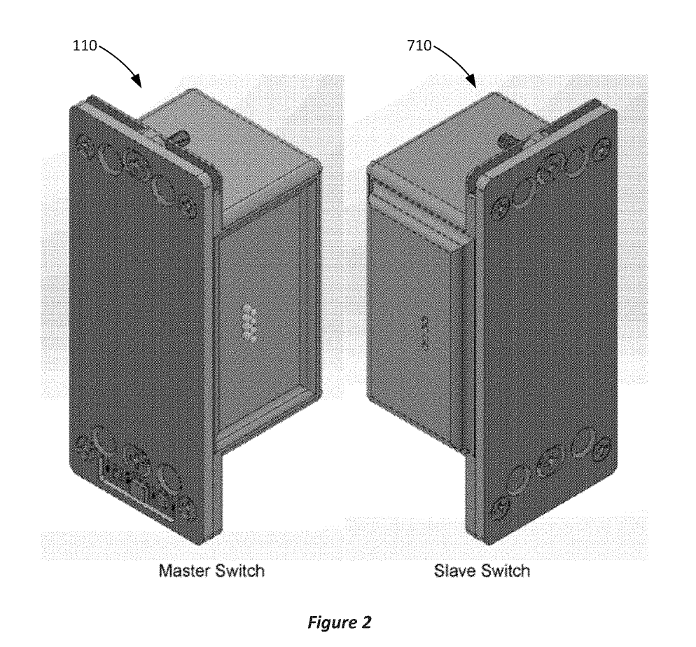

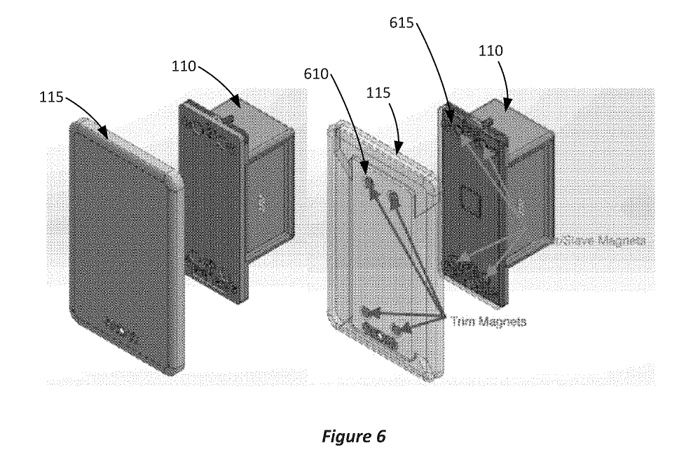

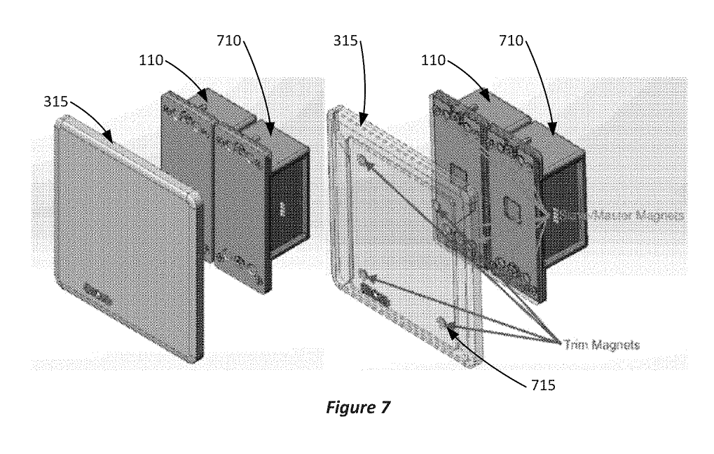

The trim panels can be coupled with the assemblies via magnets. FIG. 6 illustrates an example of coupling a trim with a switch assembly. In FIG. 6, trim panel 115 can be coupled with master assembly 110 via the use of trim magnets 610 and assembly magnets 615. However, in other implementations, trim panel 115 can “snap” into place via mechanical fastenings. FIG. 7 illustrates another example of coupling trim with a switch assembly. In FIG. 7, trim panel 315 (i.e., a trim panel for a master assembly and a slave assembly) can be larger than trim panel 310 and used to provide an interface for a user to interact with when both master assembly 110 along with a slave assembly 710 are used. Both the master assembly 110 and slave assembly 710 can include trim magnets 710 to allow for trim panel 315 to securely attach, but mechanical fastenings can also be used. FIG. 2 illustrates examples of a master assembly 110 and slave assembly 710.

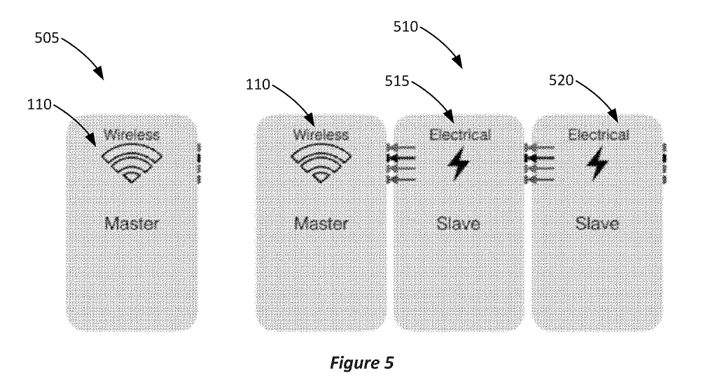

Additionally, slave assemblies can be coupled with master assembly 110 to provide a larger wall switch providing the user with additional functionalities, for example, to control another device (e.g., light) in the home. FIG. 5 illustrates an example of master and slave configurations. In FIG. 5, configuration 505 is for a wall switch with a single master assembly 110. By contrast, configuration 510 is for a three-switch wall switch with master assembly 110 and two slave assemblies 515 and 520. Master assembly 110 can include much more functionality (and therefore components) than slave assemblies 515 and 520 and, therefore, costs can be reduced by concentrating much more functionality in the master switch rather than creating redundancies within slave assemblies 515 and 520. For example, master assembly 110 can include an antenna, radio, and related circuitry such as transceivers with receivers and transmitters to provide wireless communications (e.g., via Bluetooth, Zigbee, IEEE 802.11 standards, etc.) to a home hub, router, or a cloud server. Thus, the wireless functionality need only be implemented within master assembly 110 and slave assemblies 515 and 520 can be coupled with master assembly 110 and use the wireless functionality of master assembly 110.

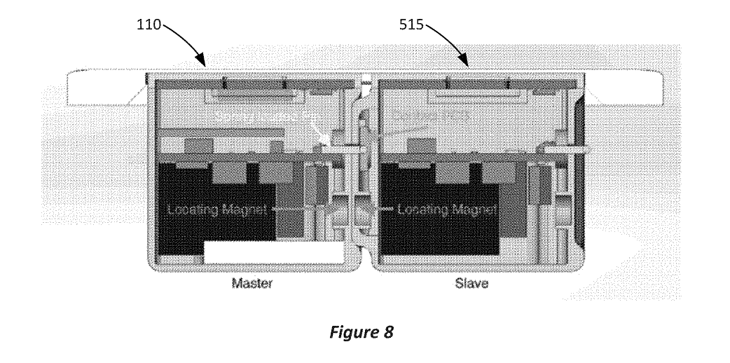

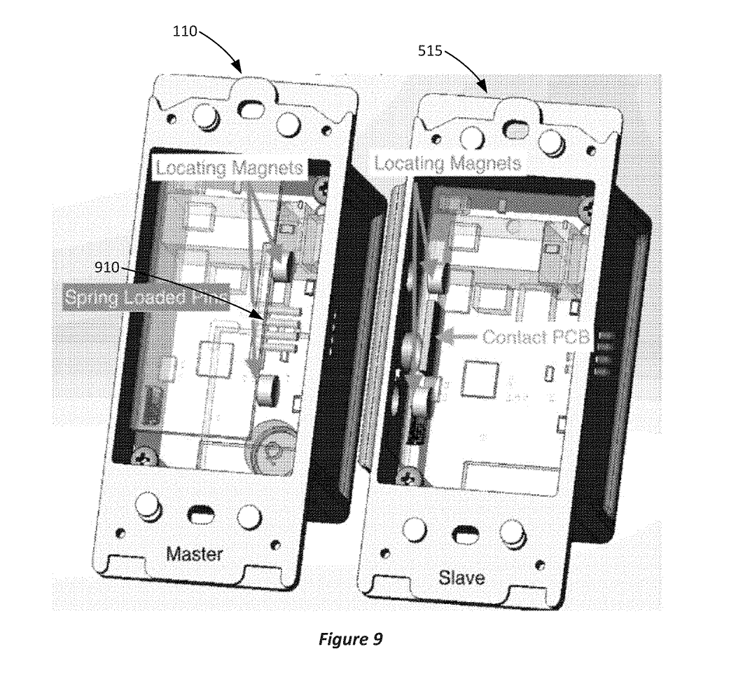

Multiple slave assemblies can be “daisy chained” together such that one slave switch at the beginning of the daisy chain coupled with master assembly 110. FIG. 8 illustrates an example of coupling a slave switch with a master switch. In FIG. 8, master assembly 110 is coupled with slave assembly 515 via the use of magnets or mechanical fastenings. The magnets or physical fastenings can ensure that the assemblies are in proper physical alignment and that they fit under the same trim panel. FIG. 9 illustrates another example of coupling a slave switch with a master switch. In FIG. 9, spring loaded pins 910 can be used ensure the mechanical alignment.

In additional, an electrical connection can be formed between master assembly 110 and slave assembly 515, and between slave assembly 515 and another slave assembly in a daisy chain. Thus, master assembly 110 can be wired into the structure's electrical system while slave assemblies are merely coupled with master assembly 110, providing easier installation and expansion of wall switches. That is, by coupling slave assemblies to a master assembly, this can result in the master assembly providing the electrical contacts to the slave assemblies without having those slave assemblies installed or wired into the structure's electrical system. Moreover, data can also be transmitted to and from master assembly 110 and slave assemblies. For example, if the user manipulates the portion of the trim panel in front of slave assembly 515, this can be determined by slave assembly 515 as an indication that the user wants to turn on a particular light because the touch detection sensor of slave assembly 515 can detect this. This determination can then be provided by slave assembly 515 to master assembly 110 and master assembly 110 can either turn on the light or provide the information to another device or cloud server (as discussed later) to turn on the light. For example, master assembly 110 can include data (e.g., in a database or other type of storage) regarding which light (or other electronic device) within the home or building that the touches in front of a particular slave assembly is supposed to adjust operation. In another example, a user can touch the part of the trim panel in front of the master assembly to turn on one light, and then touch the part of the trim panel in front of the slave assembly to turn on another light (i.e., a different light). That is, touching different parts of the trim panel can be determined by different assemblies and correlated with turning on or off different devices based on the region of the trim panel that was touched or interacted with.

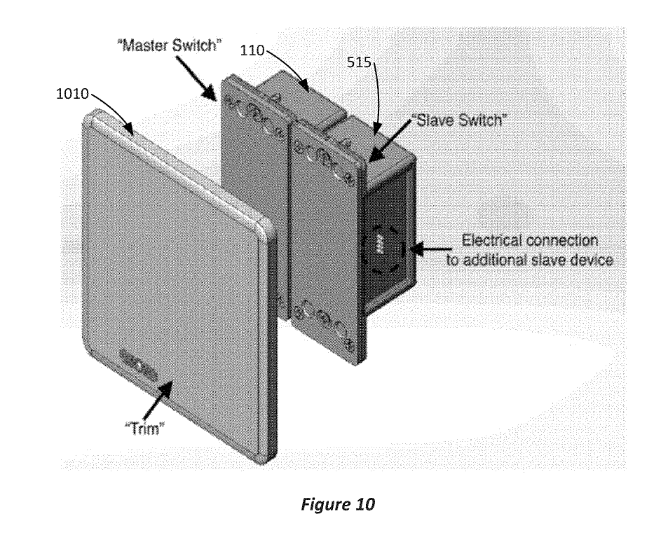

FIG. 10 illustrates an example of a trim panel for a master-slave configuration. In FIG. 10, master assembly 110 is coupled mechanically and electrically with slave assembly 515 and covered via trim panel 1010. The side of slave assembly 515 provides additional electrical and physical connections to another slave assembly for a daisy chain of slave assemblies.

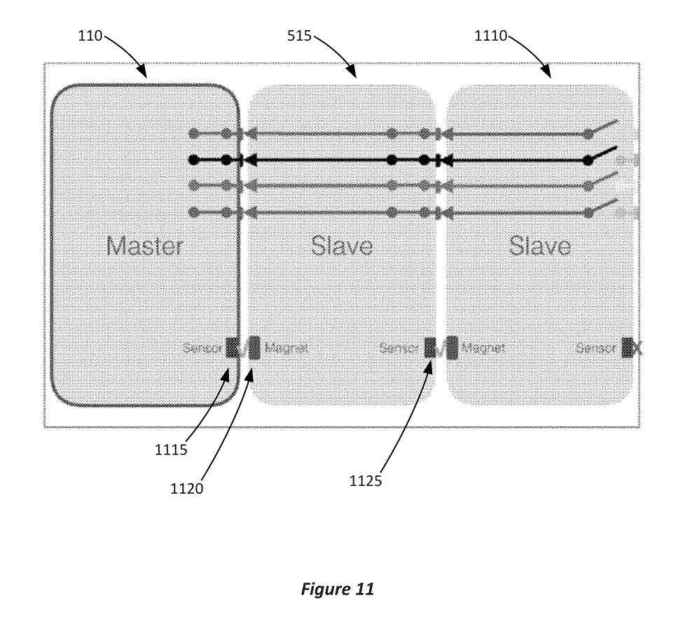

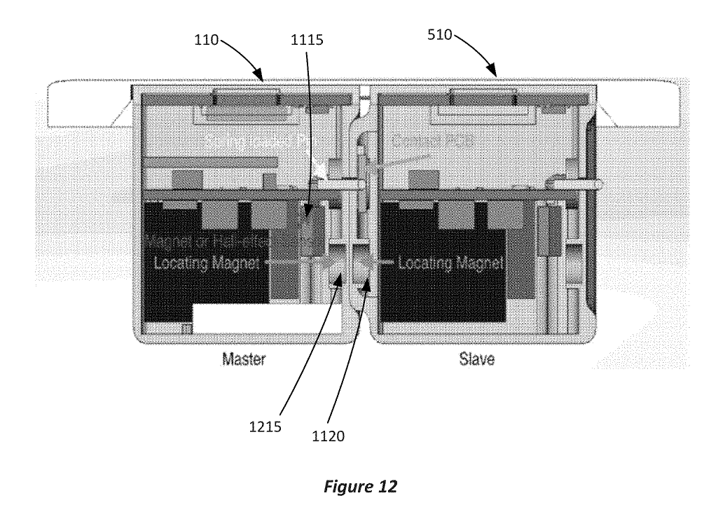

FIG. 11 illustrates an example of a master with two slave configuration. In FIG. 11, master assembly 110 is coupled to slave assembly 515. Slave assembly 515 is part of a daisy chain of slave assemblies including slave assembly 1110. As depicted in FIG. 11, master assembly 110 includes a sensor 1115 that can be used to determine whether slave assembly 515 is coupled with it via magnet 1120. For example, sensor 1115 can be a Hall Effect sensor that can detect the presence of slave assembly 515 by detecting the presence of the magnetic field produced by magnet 1120. Likewise, slave assembly 515 can include sensor 1125 on the opposite side that can be used to detect slave assembly 1110. FIG. 12 illustrates another example of a master-slave configuration. In FIG. 12, master assembly 110 includes magnet 1215 and sensor 1115. Magnet 1215 and magnet 1120 of slave assembly 1120 can attract each other to provide a physical connection. Magnets 1215 and 1120 can be opposite polarities to provide for the attraction.

In some implementations, light, proximity, capactive sensing, or other types of sensing methods other than hall effect sensors can be used. In some implementations, each assembly can perform a variety of configuration steps before enabling the communication of data to and from master assembly 110. For example, if slave assemblies 515 and 515 are daisy chained and slave assembly 515 is coupled with master assembly 110 to provide a three assembly wall switch, an I2C address can be configured to allow for the assemblies to properly communicate with each other via a bus and addressing. This can prevent addressing issues while avoiding hard coding or hardwiring specific addresses for the devices. Rather, the devices can generate their own addresses and supply the addresses to each other for the assemblies within the wall switch.

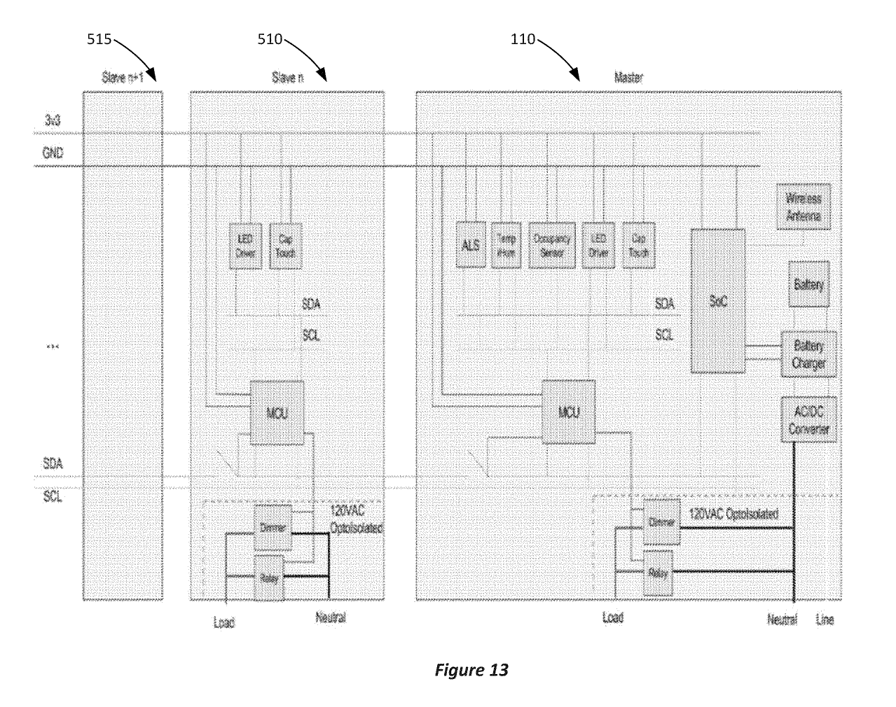

As previously discussed, master assembly 110 can include more components and implement more functionality than slave assemblies. FIG. 13 illustrates a master assembly including more functionality than a slave assembly. In FIG. 13, master assembly 110 includes significantly more components than slave assembly 510 and slave assembly 515 to reduce redundancies of components and, therefore, reduce costs.

In FIG. 13, master assembly 110 includes a wireless antenna to transmit information (e.g., to a base station or other home device or hub, or to a cloud server via a network such as the Internet), a system-on-a-chip (SoC) including processor circuitry and memory, an AC/DC converter to convert alternating current to direct current to power the components, a temperature sensor, occupancy sensor (e.g., motion detection via an infrared sensor), LED drivers (e.g., to drive, or operate, the LEDs), capacitive touch sensing circuitry, etc. By contrast, slave assembly 510 (as well slave assembly 515) only include LED drivers and capacitive touch circuitry. That is, slave assemblies don't have the temperature sensor, occupancy sensor, wireless antenna, AC/DC converter, SoC, and other components that master assembly 110 includes. Additionally, master assembly 110 includes a battery charger and battery to provide a source of backup power if the electrical system of the house or building is not operational (e.g., during a blackout).

In some implementations, master assembly 110 or one of the slave assemblies can include a night light or emergency light. For example, if a light bulb, circuit, breaker, or fuse fails, then this can be a frustrating experience for a user within the home. For example, master assembly 110 can determine the amount of current going through a circuit, voltage across a lighting circuit, resistance across a bulb that it is supposed to turn on, or power draw from a neutral line of the house's electrical system, or even include an ambient light sensor that detects that less light than expected is on. Based on these determinations, master assembly 110 can turn on an emergency light. In some implementations, master assembly 110 can also cause a notification to be sent to a user, for example, a message sent to a user's smartphone if a failure is determined and the emergency light is activated.

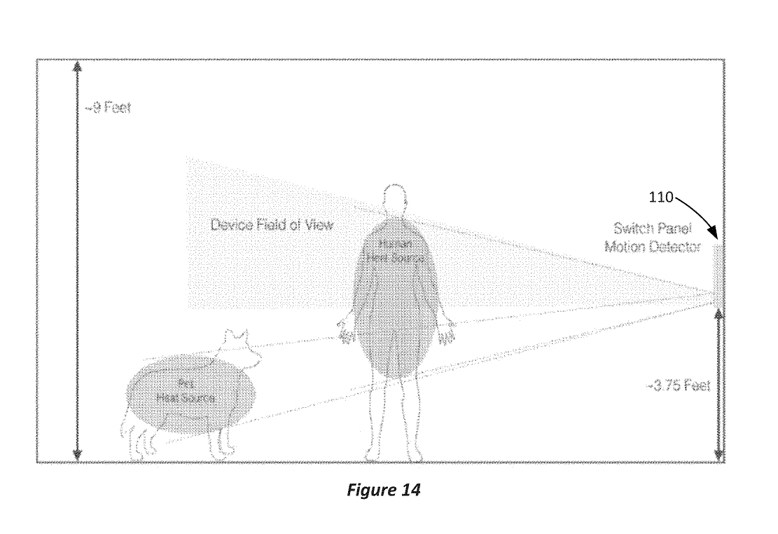

In some implementations, master assembly 110 can include an occupancy sensor, as previously discussed. For example, the occupancy sensor can detect motion occurring within a field of view of the sensor. FIG. 14 illustrates an example of a motion detector implemented within a master assembly. In FIG. 14, the occupancy sensor can be a motion sensor implemented via passive infrared (IR) sensor that can detect movement of heat within the infrared portion of the electromagnetic spectrum, an ambient light sensor, photodiode, etc. In FIG. 14, master assembly 110 is mounted on a wall to implement a wall switch. The location of the wall switch at a position for a human to operate while standing allows for the field of vision of the sensor to be above the height of pets. Thus, if motion is detected within the field of view, this is most likely a human and, therefore, occupancy (i.e., presence of a person) within the home can be determined. Thus, master assembly 110 can be part of a home security system in which motion can be detected and if so, then an alert can be provided to a homeowner, alarms can be activated, etc. However, pets would not trigger such a motion determination because pets would not be within the field of view if the sensor is mounted on the wall. In some implementations, instructions can be provided to all of the master assemblies within the home to turn on or flash all lights to serve as an alarm. Thus, a controller circuit can receive input from the occupancy sensor (e.g., infrared sensor) and determine based on that input whether the room with the wall switch is occupied.

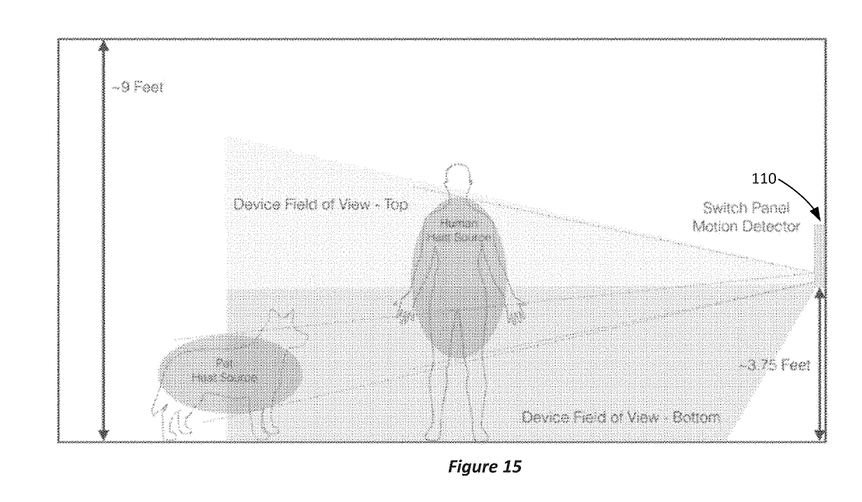

FIG. 15 illustrates another example of a motion detector implemented within a master assembly. In FIG. 15, the field of vision might be larger than in FIG. 14. However, the field of vision can be split between an upper region and a lower region. Humans would trigger motion in the upper region while pets might only trigger motion in the lower region and, therefore, a distinction can be made and alarms or alerts provided similar to the example in FIG. 14.

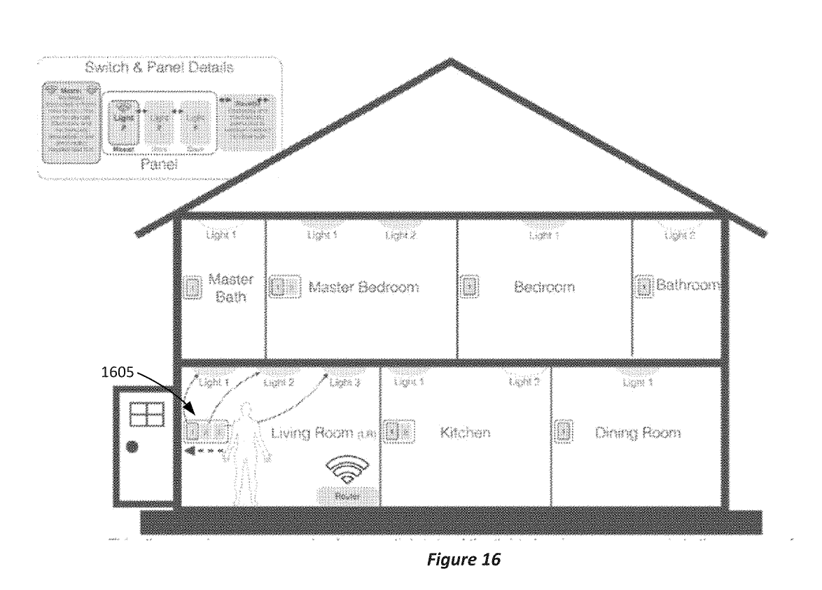

In some implementations, a user can use gestures to control the functionality described herein provided by master and slave assemblies. For example, because master assembly 110 and slave assembly 510 include touch detection capabilities, the user can provide a gesture (e.g., a movement of one or more figures in a particular pattern) on the trim panel that can be recognized by the circuitry and correlated with a particular action. For example, at any of the assemblies of a wall switch (e.g., upon the trim panel in front of master assembly 110, slave assembly 510, and/or slave assembly 515), a single gesture can be provided as an indication that the user desires to have all of the switches turn on or off. FIG. 16 illustrates an example of wall switch 1605 receiving a single gesture to turn off three lights at the same time in the living room. For example, if the user provides the gesture on a portion of the trim panel in which a slave assembly recognizes the gesture, this indication regarding the presence of the gesture can be provided to master assembly 110 because data is exchanged electrically among the assemblies. Master assembly includes wireless capabilities, as discussed previously, and, therefore, master assembly 110 can instruct the various lights to all turn on or off at once. This can provide a fast and convenient way for a user to quickly operate all of the lights at once.

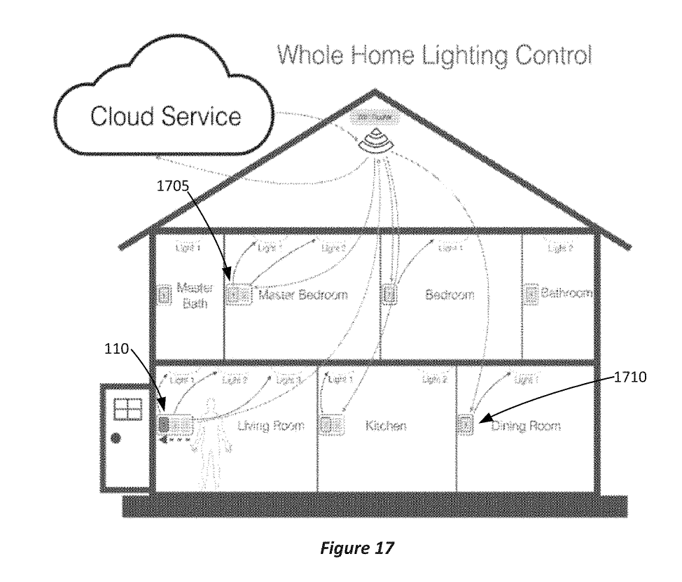

In some implementations, master assembly 110 can provide information to other master assemblies of other wall switches to turn off lights or other electronics that are controlled. For example, in FIG. 17, the user can provide a gesture upon a trim panel that master assembly 110 is behind. Master assembly 110 can then provide information, via the home's wireless network, to a cloud service, which in turn provides information back to the home's wireless network and provides instructions for other master assemblies of other wall switches to turn off the lights in the corresponding bedrooms. For example, upon the lights in the living room that master assembly 110 is within are supposed to be turned off using a gesture, information can also be provided to master assembly 1705 in the master bedroom to turn off all of the lights in that room, and information can also be provided to the other master assemblies, for example master assembly 1710 in the dining room to turn off the lights there. Thus, the user can turn off or on all of the lights in the home very quickly. In some implementations, the instructions can be provided by master assembly 110 without the use of the cloud service, for example, instructions can be provided within the home's wireless network. Similar functionality can also be used to dim or brighten lights to adjust the brightness within the home. In some implementations, the master assemblies can implement a mesh network and provide instructions directly to each other without the use of a home's wireless network that is implemented by a router.

The wall switches, via the master assemblies, can communicate with each other using IEEE 802.11 (e.g., Wi-Fi) standards, Bluetooth low energy, Zigbee, Z-Wave, or other types of personal area networks (PANs) or wireless local area networks (WLANs).

Though gestures are discussed, taps can also be used. For example, if the user taps twice upon a trim panel, the two taps can be determined and all of the lights operated by the assemblies in the same wall switch can be turned on or off. By contrast, if a single tap is determined by an assembly (i.e., the master or slave assemblies), then only a single light can be turned on, for example, a single tap in front of a slave assembly can result in the light assigned to it to be turned on.

By using the cloud service, the state of all of the lights (or other electronic devices operated by the assemblies) can be determined and available to the user. Thus, a real-time state of the environment of the home can be determined.

In some implementations, assemblies in different wall switches can operate the same light. The user can use an app of a smartphone to indicate that different assemblies are to operate the same light. Thus, the user can implement a variety of customizations.

In some implementations, an assembly can be automatically assigned to receive user input for controlling a light. For example, the light closest to an assembly can be determined and used to adjust the operation of the light. For example, an ambient light sensor can be included in each assembly and the difference between the measured amount of light using the ambient light sensor before the light is turned on and after the light is turned on can be determined. This “light delta” can be determined for several different assemblies and/or among different wall switches. The one with the largest light delta can be determined to be the assembly or wall switch closed to the light and, therefore, be configured to control that light.

In some implementations, dimming can be implemented and using the ambient light sensor, the amount of dimming can be adjusted based o the amount of natural sunlight (or light) determined. Thus, if the sun is shining in the same room as a master assembly 110 of a wall switch, then the light can be turned off. As the time approaches sunset, less sunlight might be in the room and, therefore, the light can be progressively increased in intensity such that the room maintains a certain level of brightness.

The distribution of master assemblies can be within several different rooms or locations within a home. In some implementations, the master assemblies (or slave assemblies) can include pressure sensors that can be used to detect when doors or windows are opened or closed. For example, as doors or windows are opened, a change in pressure can be detected based on the opening (or closing) of the doors or windows. By each wall switch providing a determination regarding the pressure, a pressure wave can be triangulated to determine the origin of the pressure wave to a particular room or even a particular door or window. An alarm, as previously discussed, can then be activated to alert people within the home.

Temperature and humidity sensors can also be provided and used as an input to a HVAC system to provide air conditioning or heating. Because the wall switches are distributed within the home and different rooms, this can provide “zoned” temperature and humidity data rather than a single thermostat reading from a single location within the home.

Master assemblies 110 can also include other types of environmental sensors including air quality sensors, for example, volatile organic compound (VOC), carbon monoxide, carbon dioxide, methane, radon, etc. sensors can be implemented within the switch panels and alarms can be provided if the levels of the detected variables of the sensors are beyond a threshold amount. In some implementations, occupancy can be determined via, or supplemented with, methane or carbon dioxide measurements.

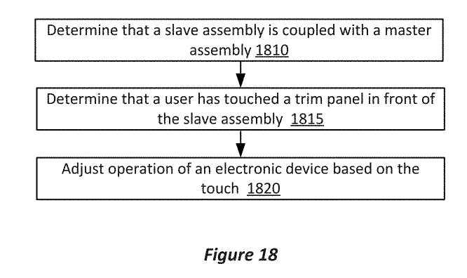

FIG. 18 illustrates an example of a block diagram for a master and slave assembly operation. In FIG. 18, at block 1810, a master assembly can determine that a slave assembly has been coupled with the master assembly. For example, in FIG. 11, the sensor 1115 can be a hall effect sensor that can determine the presence of the magnetic field of magnet 1120 of slave assembly 515. A controller circuit can receive this determination from the hall effect sensor and upon determining that slave assembly 515 has been coupled with master assembly 110, the assemblies can configure addresses and inform each other as to which devices in the environment are to be controlled by touch gestures that are detected by the respective touch sensitive circuitry of master assembly 110 and slave assembly 515. In some implementations, master assembly 110 can receive data indicating the assignments of which device in the environment are to be controllable by which assembly, for example, via a smartphone app controlled by the user. At block 1815, the master assembly can determine that a portion of the trim panel in front of both the master assembly and slave assembly has been touched in a region in front of the slave assembly. For example, the touch sensor of slave assembly 515 can determine that a user has touched the trim panel in front of slave assembly 515 and data indicating this can be provided to master assembly 110 because the assemblies are both communicatively coupled with each other.

In some implementations, light bulbs controllable by the master assembly and slave assemblies described herein can be communicated with using data over power lines. This can result in cost savings because hardware for power line communications can be cheaper than hardware for wireless communications.

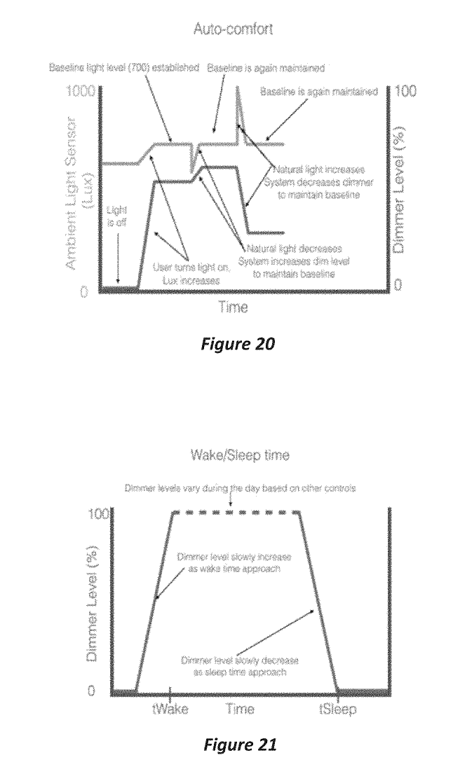

In some implementations, the master assembly or the slave assembly can include ambient light sensors to measure the amount of light within the environment. For example, in FIG. 20, the graph shows a level of the determined ambient light. The baseline for the ambient light can be set when the light controlled by the master assembly is turned off. If the natural light decreases beyond a certain threshold, then the switch can be instructed to raise the dimmer level in order to attain the original baseline light level. If the natural light levels increase beyond a threshold, then the dimmer level can be decreased in order to maintain the baseline ambient light level. In another example, FIG. 21 shows adjusting the dimmer level for sleeping or waking a user. In FIG. 21, the dimmer level can be increased to allow more light when the wake time is approaching and the dimmer level can be decreased to reduce the light when sleep time is approaching.

In some implementations, a microphone and speaker can be implemented within an assembly (e.g., a master assembly) and used to implement an intercom system to provide communications across a home to another assembly. This can allow for people in different rooms to communicate with each other. In some implementations, the microphone and speaker to implement this intercom system can be implemented within a slave assembly that can be coupled with the master assembly, as previously discussed. Additionally, voice assistants providing artificial intelligence (AI) capabilities can be provided.

In some implementations, the microphone and speaker can be used to implement echolocation for physical mapping of devices within the home. For example, an ultrasonic signal can be emitted using the microphone. Audio processing using a digital signal processor (DSP) or other controller circuit can be used to analyze input received from the microphone which can include reflections of the ultrasonic signal off of objects within the environment. The time difference between transmitting the ultrasonic signal and receiving the reflections can be used to determine a physical distance between the devices and the assembly. This can allow for a mapping of the home environment to be performed.

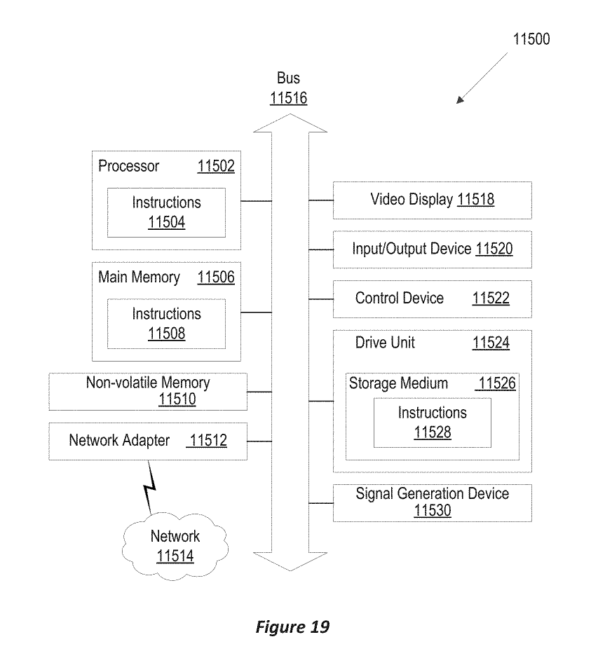

FIG. 19 illustrates an example of a device for a master assembly or a slave assembly. For example, FIG. 19 is a block diagram illustrating an example of a processing system 11500 in which at least some operations described herein can be implemented. Processing system 11500 can include the components described above (e.g., sensors, magnets, etc.) as well as the processing system 11500 may include one or more central processing units (“processors”) 11502, main memory 11506, non-volatile memory 11510, network adapter 11512 (e.g., network interface), video display 1518, input/output devices 11520, control device 11522 (e.g., keyboard and pointing devices), drive unit 11524 including a storage medium 11526, and signal generation device 11530 that are communicatively connected to a bus 11516. The bus 11516 is illustrated as an abstraction that represents one or more physical buses and/or point-to-point connections that are connected by appropriate bridges, adapters, or controllers. The bus 11516, therefore, can include a system bus, a Peripheral Component Interconnect (PCI) bus or PCI-Express bus, a HyperTransport or industry standard architecture (ISA) bus, a small computer system interface (SCSI) bus, a universal serial bus (USB), IIC (I2C) bus, or an Institute of Electrical and Electronics Engineers (IEEE) standard 11394 bus (also referred to as “Firewire”).

The processing system 11500 may share a similar computer processor architecture as that of a desktop computer, tablet computer, personal digital assistant (PDA), mobile phone, game console, music player, wearable electronic device (e.g., a watch or fitness tracker), network-connected (“smart”) device (e.g., a television or home assistant device), virtual/augmented reality systems (e.g., a head-mounted display), or another electronic device capable of executing a set of instructions (sequential or otherwise) that specify action(s) to be taken by the processing system 11500.

While the main memory 11506, non-volatile memory 11510, and storage medium 526 (also called a “machine-readable medium”) are shown to be a single medium, the term “machine-readable medium” and “storage medium” should be taken to include a single medium or multiple media (e.g., a centralized/distributed database and/or associated caches and servers) that store one or more sets of instructions 11528. The term “machine-readable medium” and “storage medium” shall also be taken to include any medium that is capable of storing, encoding, or carrying a set of instructions for execution by the processing system 11500.

In general, the routines executed to implement the embodiments of the disclosure may be implemented as part of an operating system or a specific application, component, program, object, module, or sequence of instructions (collectively referred to as “computer programs”). The computer programs typically comprise one or more instructions (e.g., instructions 11504, 11508, 11528) set at various times in various memory and storage devices in a computing device. When read and executed by the one or more processors 11502, the instruction(s) cause the processing system 11500 to perform operations to execute elements involving the various aspects of the disclosure.

Moreover, while embodiments have been described in the context of fully functioning computing devices, those skilled in the art will appreciate that the various embodiments are capable of being distributed as a program product in a variety of forms. The disclosure applies regardless of the particular type of machine or computer-readable media used to actually effect the distribution.

Further examples of machine-readable storage media, machine-readable media, or computer-readable media include recordable-type media such as volatile and non-volatile memory devices 11510, floppy and other removable disks, hard disk drives, optical disks (e.g., Compact Disk Read-Only Memory (CD-ROMS), Digital Versatile Disks (DVDs)), and transmission-type media such as digital and analog communication links.

The network adapter 11512 enables the processing system 11500 to mediate data in a network 11514 with an entity that is external to the processing system 11500 through any communication protocol supported by the processing system 11500 and the external entity. The network adapter 11512 can include a network adaptor card, a wireless network interface card, a router, an access point, a wireless router, a switch, a multilayer switch, a protocol converter, a gateway, a bridge, bridge router, a hub, a digital media receiver, and/or a repeater.

The network adapter 11512 may include a firewall that governs and/or manages permission to access/proxy data in a computer network, and tracks varying levels of trust between different machines and/or applications. The firewall can be any number of modules having any combination of hardware and/or software components able to enforce a predetermined set of access rights between a particular set of machines and applications, machines and machines, and/or applications and applications (e.g., to regulate the flow of traffic and resource sharing between these entities). The firewall may additionally manage and/or have access to an access control list that details permissions including the access and operation rights of an object by an individual, a machine, and/or an application, and the circumstances under which the permission rights stand.

The techniques introduced here can be implemented by programmable circuitry (e.g., one or more microprocessors), software and/or firmware, special-purpose hardwired (i.e., non-programmable) circuitry, or a combination of such forms. Special-purpose circuitry can be in the form of one or more application-specific integrated circuits (ASICs), programmable logic devices (PLDs), field-programmable gate arrays (FPGAs), etc.

I/We claim:

1. A wall switch, comprising:
a slave assembly having a magnet configured to generate a magnetic field;
a master assembly having a hall effect sensor configured to detect the magnetic field generated by the magnet, and a controller circuit configured to determine that hall effect sensor has detected the magnetic field indicating that the slave assembly is coupled with the master assembly; and
a trim panel coupled with both the slave assembly and the master assembly, the trim panel providing a surface covering both the slave assembly and the master assembly.

2. The wall switch of claim 1, wherein the master assembly includes a first touch sensitivity sensor configured to detect a first interaction with the trim panel.

3. The wall switch of claim 2, wherein the slave assembly includes a second touch sensitivity sensor configured to detect a second interaction with the trim panel.

4. The wall switch of claim 3, wherein the first interaction and the second interaction with the trim panel are on different locations of the trim panel.

5. The wall switch of claim 4, wherein the first interaction corresponds to a first location in front of the master assembly, and the second interaction corresponds to a second location in front of the slave assembly.

6. The wall switch of claim 1, wherein the trim panel is magnetically coupled with the slave assembly and the master assembly.

7. The wall switch of claim 1, wherein the master assembly includes an infrared sensor, and the controller circuit is configured to determine occupancy of an environment including the wall switch based on the infrared sensor.

8. The wall switch of claim 7, wherein the slave assembly does not include an infrared sensor.

9. The wall switch of claim 1, wherein the master assembly includes a visual indicator providing information related to a state of an electronic device within the environment.

10. The wall switch of claim 1, wherein the master assembly includes a wireless transceiver configured to communicatively couple with a wireless network of an environment of the wall switch.

11. A method, comprising:
determining, by a processor of a master assembly, that a slave assembly has coupled with the master assembly to implement a wall switch;
determining, by the processor, presence of a first touch on a first portion of a trim panel in front of the slave assembly; and
adjusting, by the processor, operation of an electronic device within an environment of the wall switch based on the first touch of the portion of the trim panel in front of the slave assembly.

12. The method of claim 11, further comprising:
determining, by the processor, presence of a second touch on a second portion of the trim panel in front of the master assembly; and
adjusting, by the processor, operation of a second electronic device within the environment based on the second touch.

13. The method of claim 11, wherein determining that the slave assembly has coupled with the master assembly includes:
detecting, by the processor, a presence of a magnetic field generated by a magnet of the slave assembly device.

14. The method of claim 13, wherein the presence of the magnetic field is detected using a hall effect sensor.

15. The method of claim 11, wherein adjusting the operation of the electronic device includes the master assembly providing an instruction to the electronic device to adjust the operation.

16. A system, comprising:
a master assembly of a wall switch;
a trim panel coupled with the master assembly, wherein the master assembly includes a touch sensor configured to detect presence of a first touch upon the trim panel, and adjust operation of a device within an environment of the wall switch based on the first touch.

17. The system of claim 16, further comprising:
a slave assembly coupled with the master assembly to implement a wall switch configured to adjust operation of the device and a second device.

18. The system of claim 17, wherein the master assembly includes a sensor configured to detect that the slave assembly is coupled with the master assembly.

19. The system of claim 18, wherein the sensor is a hall effect sensor.

20. The system of claim 19, wherein the slave assembly includes a magnetic, and the hall effect sensor is configured to detect a presence of a magnetic field of the magnetic to determine that the slave assembly is coupled with the master assembly.

21. The system of claim 17, wherein the trim panel is also coupled with the slave assembly.

22. The system of claim 21, wherein the master assembly and the slave assembly are coupled with the trim panel via magnets.

23. The system of claim 16, wherein the master assembly includes a temperature sensor.

24. The system of claim 16, wherein the master assembly includes an environmental sensor.
